(19) United States
(12) Patent Application Publication
(10) Pub. No.: US 2002/0180521 A1
(43) Pub. Date: Dec. 5, 2002

(54) Method and apparatus for improved power control of radio frequency power amplifiers

(76) Inventor: Stewart Sidney Taylor, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/873,496

(22) Filed: Jun. 4, 2001

(51) Int. Cl. H03G 3/20

(52) U.S. Cl. 330/129

(57) ABSTRACT

A method and apparatus for improved power control of a radio frequency power amplifier achieved by limiting the maximum power of the radio frequency signal and varying the power of the radio frequency signal according to one or more power control feedback signals. In particular, the maximum power is limited by limiting the average current of the RF signal to a predetermined maximum value, despite the changing amplitude of the RF signal, thereby limiting the power of the radio signal and preventing the power control signals to the power varying circuit from being overwhelmed and/or maintaining stability.

### BACKGROUND OF THE INVENTION

1. Field

The present invention pertains to power amplifiers and in particular to methods and apparatus for power control of radio-frequency power amplifiers.

2. Background

RF power amplifiers are used in many applications, including portable communication devices for transmitting analog and digital information. In many applications, the RF broadcast power provided by such devices is controlled by the base station based upon the strength of the received signal. Accordingly, RF amplifiers in such devices need to be able to transmit the maximum RF power required for such a device when necessary, yet transmit RF signals at lower power levels when applicable, and to transmit such RF signals efficiently to extend the battery usage between required recharges. Accordingly, variable gain power amplifier systems are generally required for these, as well as other uses.

Some prior art variable gain RF circuits do not limit the amplitude of the RF signal entering the amplitude varying circuitry providing the variable gain capability, thus degrading performance or requiring additional filtering and/or low impedance interface circuitry, which increases power dissipation. Other prior art circuits offset the sum of the bias voltage and the RF signal passing through the amplifier. This latter approach has limited usefulness when dealing with large RF signals. The present invention maintains a relatively constant input reflection coefficient with varying input power levels and facilitates using a single power supply pin for the input amplifier and power control combination.

### BRIEF DESCRIPTION OF THE DRAWINGS

FIG. 1 is a system-level diagram illustrating an embodiment of the amplifier power control system of the present invention.

FIG. 2 is a more detailed circuit diagram illustrating an embodiment of the power control system shown in FIG. 1.

FIG. 3 is a detailed circuit diagram illustrating an embodiment of the power control system shown in FIG. 1 utilizing field effect transistors for the VGA.

FIG. 4 illustrates a specific embodiment of an amplifier power control circuit in accordance with FIG. 2.

FIG. 5A is a waveform diagram illustrating how the stage 1 amplifier of FIGS. 2, 3, and 4 may operate as a class A amplifier.

FIG. 5B is a waveform diagram illustrating the stage 1 amplifier of FIGS. 2, 3, and 4 in the limit of class A operation.

FIG. 5C is a waveform diagram illustrating the stage 1 amplifier of FIGS. 2, 3, and 4 operating beyond class A operation, such as class AB, B or C.

FIG. 6 illustrates an alternate embodiment of an amplifier power control circuit.

FIG. 7 illustrates a further alternate embodiment of an amplifier power control circuit.

### DETAILED DESCRIPTION OF THE PREFERRED EMBODIMENT

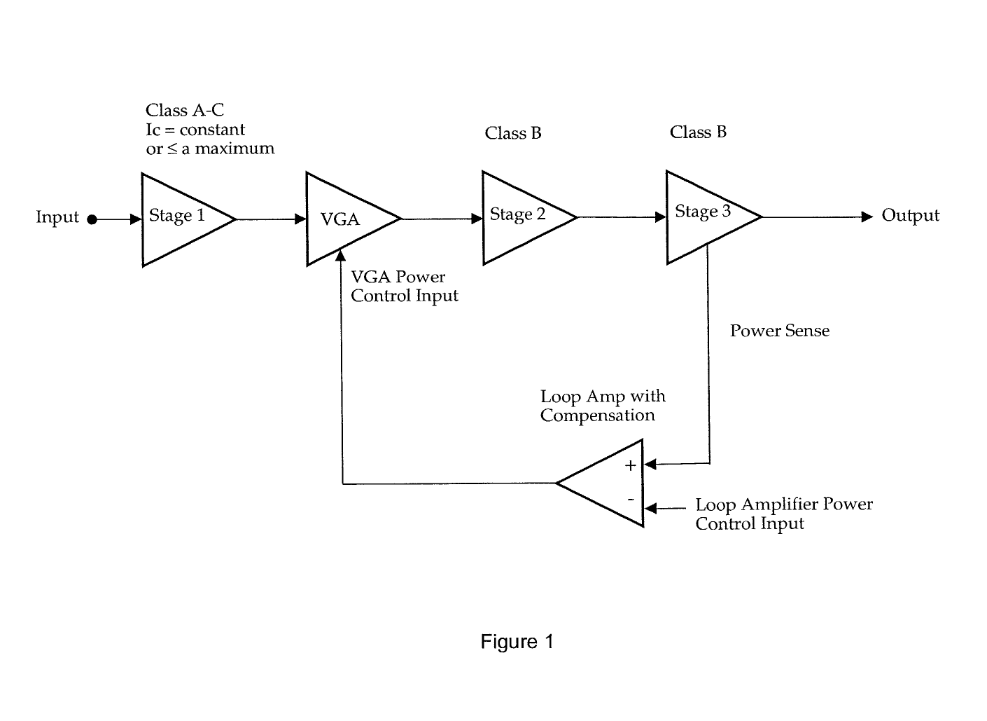

FIG. 1 illustrates an exemplary application of one embodiment of the power control of radio frequency power amplifiers of the present invention. The invention may be practiced with a single or multi-stage power amplifier, though for purposes of explanation herein, a multi-stage power amplifier is shown. Specifically the power amplifier system shown comprises a first stage (Stage 1), a Variable Gain Amplifier (VGA) stage, a class B stage (Stage 2) and a class B output stage (Stage 3). Alternatively, the Stage 2 and Stage 3 amplifiers may operate as class AB, class C amplifiers or a combination of these. In one embodiment, Stage 1 and the VGA Amplifier comprise amplifiers having improved power control in accordance with the present invention.

In various implementations the power amplifier stages, Stage 1, Stage 2, and/or Stage 3, may include one or more transistors. Various types of transistors may be employed including bipolar junction transistors (BJT), and/or field effect transistors (FET). Field effect transistors that may be used may include junction FETs, metal-oxide-semiconductor (MOS) FETs or metal semiconductor FETs (MESFETs). Also by way of example, high electron mobility transistors (HEMTs, PHEMTs and MODFETs) or other compound semiconductors may also be used. For example, the VGA stage (Stage 2) may be implemented with either bipolar transistors or MOSFETs. A person of ordinary skill in the art will recognize that many of the exemplary embodiments disclosed herein may be interchangeably practiced using bipolar and/or field effect transistors.

The embodiment shown in FIG. 1 is suitable for use in wireless devices such as cell phones and the like. In such devices, a single channel signal is amplified for broadcast with a gain typically dictated by the base station based on the strength of the signal received by the base station. Thus one or more power control input signals may be provided to the amplifier system, such as the Loop Amplifier Power Control Input signal provided to the Loop Amplifier shown in FIG. 1. In the case of the VGA, the Power Control Input comprises an error signal derived from a comparison of an output feedback signal, such as from an output coupler and detector as is known in the art and the Loop Amplifier Power Control Input.

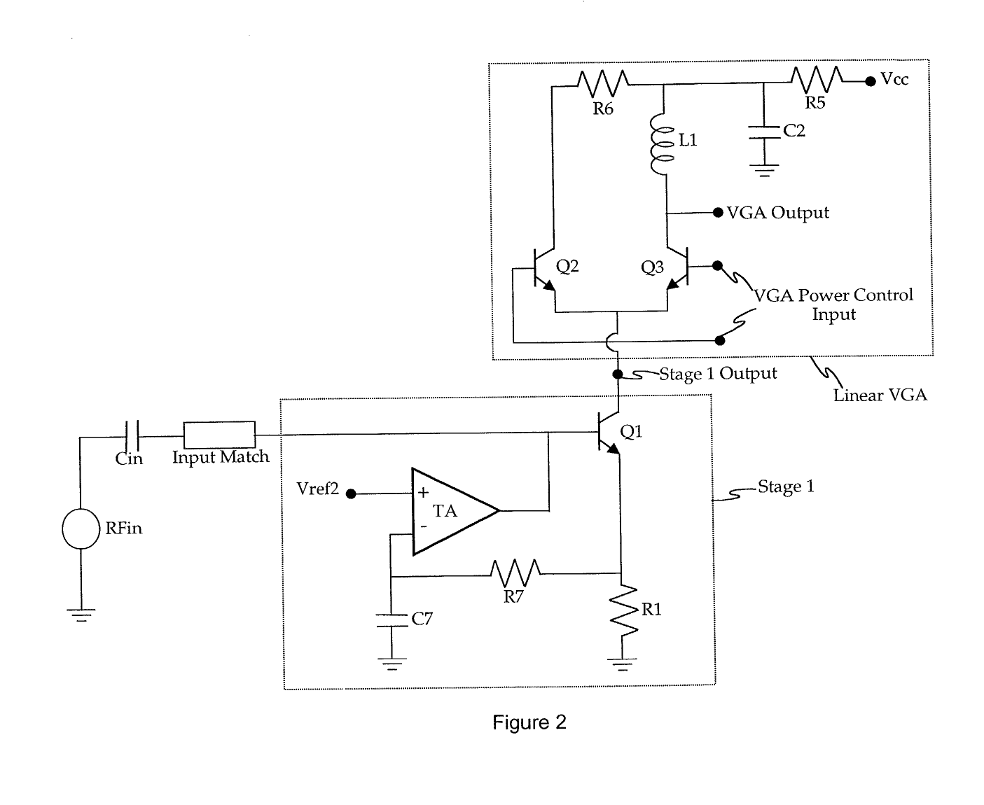

FIG. 2 illustrates one embodiment of the present invention that may be used in the Stage 1 amplifier and VGA of FIG. 1. In this embodiment, the Stage 1 amplifier may comprise a common-emitter amplifier, transistor Q1, to amplify an RF signal RFin to provide an output signal. The VGA stage may comprise differential output current steering transistors Q2 and Q3 controlled by a differential VGA Power Control Input signal, with the output taken from the collector of transistor Q3. In another embodiment, a single ended Power Control Input signal may be used, such as by coupling the base of Q2 to a reference voltage and the base of Q3 to the single ended VGA Power Control Input. The VGA Power Control Input signal is typically derived from an interface circuit as is well known in the art, the interface circuit providing the level shifting and drive current required for the output current steering transistors.

Typically, the greater the amplitude of the signal coming from the common-emitter amplifier Q1, the lower the impedance required and the greater the power dissipation in the interface circuit providing the VGA Power Control Input signal to the VGA. If the signal from transistor Q1 is sufficiently large, it is possible that an RF signal on the emitters of transistors Q2 and Q3 could overwhelm the VGA Power Control Input signal base drive for transistors Q2 and Q3 from the interface circuit and disrupt power control operation. The present invention overcomes these limitations by limiting the amplitude of the signal coming from the common-emitter amplifier Q1.

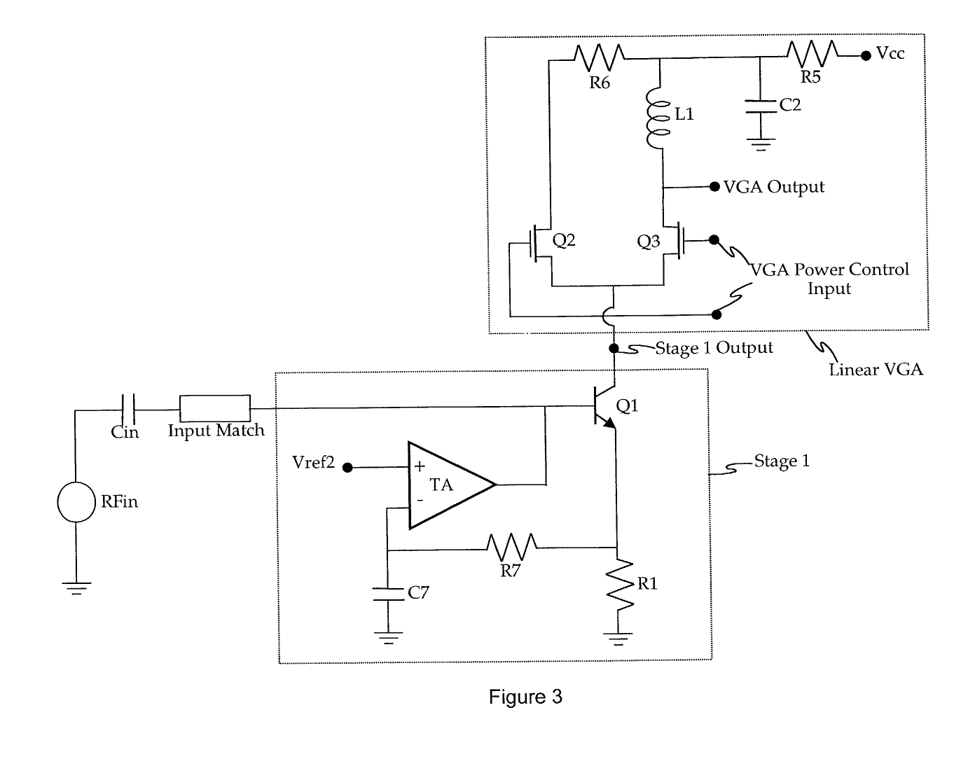

Note that transistors Q2 and Q3 may be of various transistor types without departing from the invention. In one embodiment, illustrated in FIG. 2, transistors Q2 and Q3 may be bipolar transistors. In another embodiment, illustrated in FIG. 3, transistor Q2 and Q3 may be field effect transistors.

In the embodiment shown in FIG. 2, the output of a transconductance amplifier TA is coupled to the base of transistor Q1 to maintain an approximately fixed average collector current in transistor Q1 despite a changing RF input signal. The inverting input terminal of the transconductance amplifier is coupled to the emitter of the transistor Q1 through resistor R7, with resistor R7 and capacitor C7 forming a low-pass filter to filter out the RF signal. The non-inverting input terminal of the transconductance amplifier TA is coupled to a reference voltage Vref2 to hold the DC bias current in transistor Q1 substantially equal to Vref2/R1. By selecting an appropriate reference voltage level Vref2 and value of resistor R1, the average current in transistor Q1 may be held to the desired value. In one embodiment, the reference voltage level Vref2 and the value of resistor R1 are chosen to fix the average current in transistor Q1 to a value corresponding to the maximum power desired for the VGA. Accordingly, by limiting the average current in transistor Q1, the transconductance amplifier TA limits or regulates the current that may flow through the collector of transistor Q1, thus reducing the power of the signal passing through the VGA.

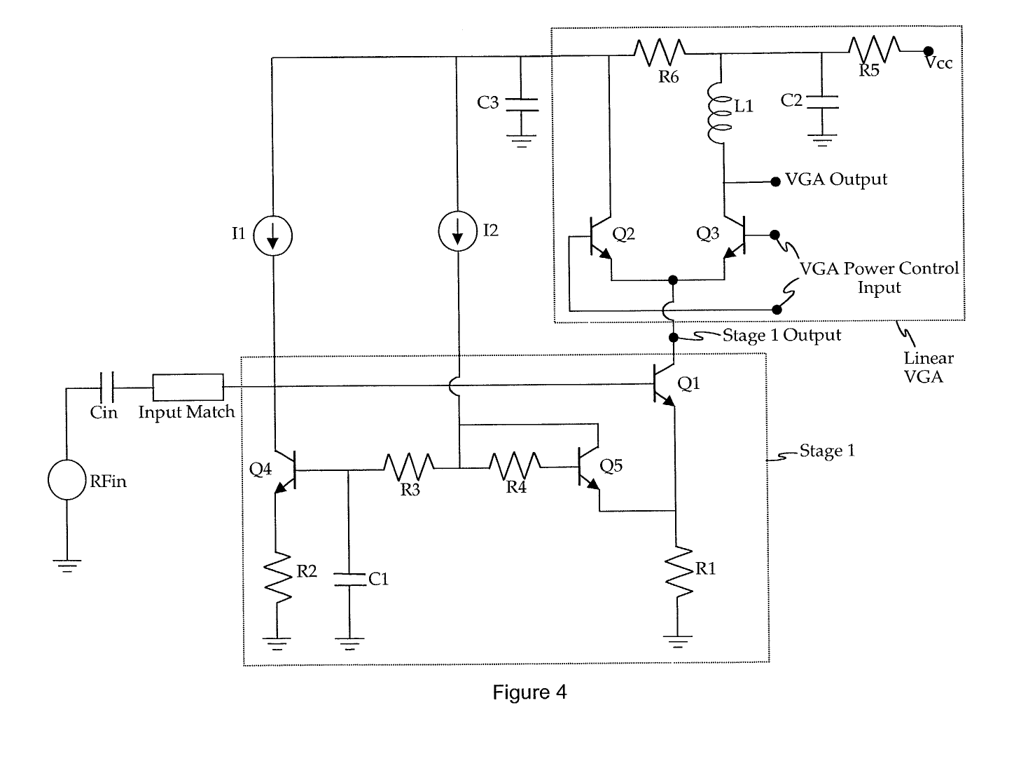

FIG. 4 is a circuit diagram for an embodiment of the present invention in accordance with FIG. 2. As shown therein, the amplifier stage may comprise a common-emitter RF amplifier Q1 with regulating bias means resistors R1, R2, R3, and R4, capacitor C1, transistors Q4 and Q5, and current sources I1 and I2. As with the embodiment shown in FIG. 2, transistors Q2 and Q3 provide output current steering (collector current of transistor Q1) between transistors Q2 and Q3. Common-emitter amplifier Q1 has input matching means known to those skilled in the art. The output OUT of the amplifier stage is taken from the collector of transistor Q3, with inductor L1 forming part of a matching network for interfacing to the next stage. As with the embodiment in FIG. 2, the amplifier stage gain control is driven differentially (a single ended drive may be used if desired) from an interface by a Power Control Input coupled to the bases of transistors Q2 and Q3. The interface may have non-zero driving point impedance related to the magnitude of the signal coming from the amplifier Q1. Typically, the greater the amplitude of the signal coming from Q1, the lower the driving point impedance and the greater the power dissipation of the interface circuit to adequately drive the bases of transistors Q2 and Q3. Note that the current steering transistors Q2 and Q3 may also be implemented using FET transistors as illustrated in the VGA of FIG. 3.

Biasing means comprising resistors R1, R2, R3, R4, capacitor C1, transistors Q4 and Q5, and current sources I1 and I2 form a negative feedback loop with transistor Q1 that is operative at low frequencies, regulating the average collector current of transistor Q1 to be approximately constant. This loop is inoperative at RF frequencies because the low-pass filter comprising resistor R3 and capacitor C1 substantially removes or filters out the RF signal, preventing it from entering the base of Q4.

The biasing means illustrated in FIG. 4 operates in the following way. Assuming that beta is infinite (base currents in transistors Q4 and Q5 are zero) and V_{be4}=V_{be5} (where V_{be4} is the base-emitter voltage of Q4 and V_{be5} is the base-emitter voltage of Q5), then the current through transistor Q4 and resistor R2 will be the current I1, and the current through transistor Q5 and resistor R1 will be the current I2. Thus:

I1R2=(I2+I_{c1})R1, or

$${I}_{c1} = I1 \frac{R2}{R1} - I2$$

where I_{c1} is the collector current of Q1.

In practice this result will vary somewhat because beta is finite and because of the voltage drop across resistor R3. Components R4, I1, and I2 can be adjusted to produce the desired result. Typical bias currents in a wireless device might be I1=I2=0.2 mA to 1 mA, with a collector current of transistor Q1, I_{c1}=3 mA to 10 mA. The product of R3 and C1 may typically be chosen to equal 25-100 nS. In this embodiment, resistor R1 is chosen to produce a relatively small voltage drop, typically 30 mV to 60 mV, so as not to reduce the voltage/power gain of transistor Q1 or reduce the voltage swing available from the collector of transistor Q3. Of course these values are exemplary only, and not a limitation of the invention.

Circuitry employing resistor R1 alone might drop significant voltage, lowering the gain and/or limiting the voltage swing at the collector of transistors Q3. The filters comprising resistor R5 and capacitor C2, and resistor R6 and capacitor C3 provide filtering, allowing the collectors of transistors Q2 and Q3 to be connected to the same (single) voltage supply pin. This might not be possible if the power coming from transistor Q1 was not limited by the biasing means. A further benefit of regulating the collector current of transistor Q1 to be constant is that the reflection coefficient, S11, of the input to transistor Q1 will remain relatively constant with varying input power.

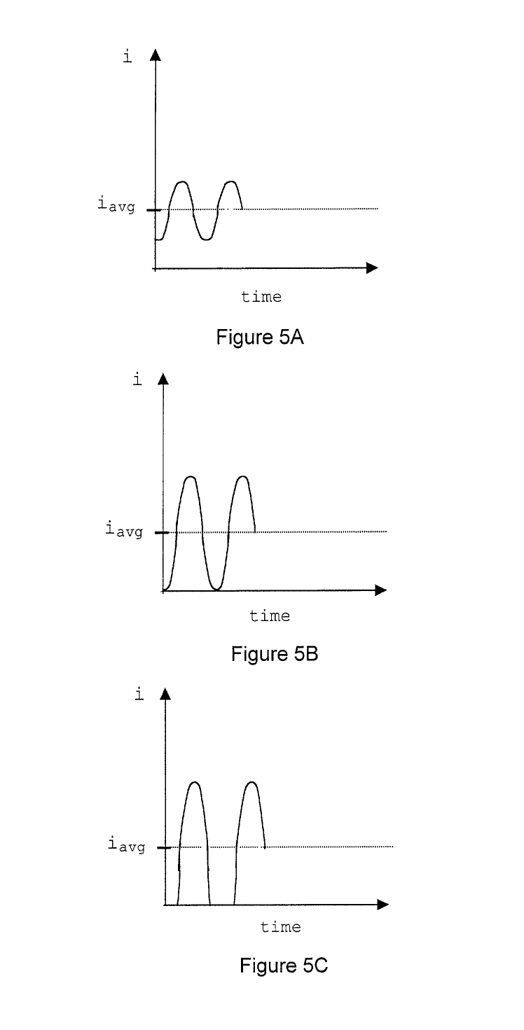

Because the average DC collector current in transistor Q1 is held substantially constant by the regulating DC negative feedback loop of the biasing means of transistor Q1, the maximum output power delivered to transistors Q2 and Q3 is limited to a value that does not disrupt the operation of the VGA stage. In particular, consider the small signal and large signal operation of the transconductance amplifier Q1 with a sinusoidal input signal. For a small signal input (RFin is small), transistor Q1 acts as a class A transconductance amplifier, with a collector current as illustrated in FIG. 5A. In the limit, the collector current may swing from approximately zero to twice the average collector current set by the biasing circuit to still maintain class A operation, as illustrated in FIG. 5B. In either case, the average collector current component in transistor Q1 resulting from the input signal RFin is substantially constant or unchanged. For larger input signals, the negative going collector current waveform becomes clipped, as the circuit will not support negative collector currents in transistor Q1. Consequently, clipping only the negative going current waveform results in an average collector current component in transistor Q1 from a large input signal RFin that is substantially above zero, and increases with increases in the input signal RFin. Since the present invention maintains the total average collector current in transistor Q1 substantially constant, the present invention will reduce the DC bias on the base of transistor Q1. This in turn lowers the positive swing in the collector current of transistor Q1, and in fact the entire waveform of the collector current, increasing the negative going waveform clipping until the area of the current waveform above the average collector current set by the present invention is substantially equal to the area of the clipped waveform below the average collector current set by the present invention. Consequently, maintaining the total average collector current in transistor Q1 substantially constant limits the positive going collector current as well as the negative going collector current from a large RF input signal to limit the current input to and power output of the VGA stage.

Thus at low power levels, transistor Q1 operates as a class A amplifier (a conduction angle of 360 degrees) with high gain. This is important when high gain is necessary in the complete amplifier. As the magnitude of the input signal RFin increases, transistor Q1 begins to operate in a class AB mode, where the conduction angle is less than 360 degrees but more than 180 degrees, and then in a class B mode (illustrated in FIG. 5C), where the conduction angle is 180 degrees. If the input signal RFin is sufficiently large, transistor Q1 may operate in a class C mode where the conduction angle of the signal is less than 180 degrees. This is a consequence of regulating the average current to be constant or fixed while overdriving transistor Q1.

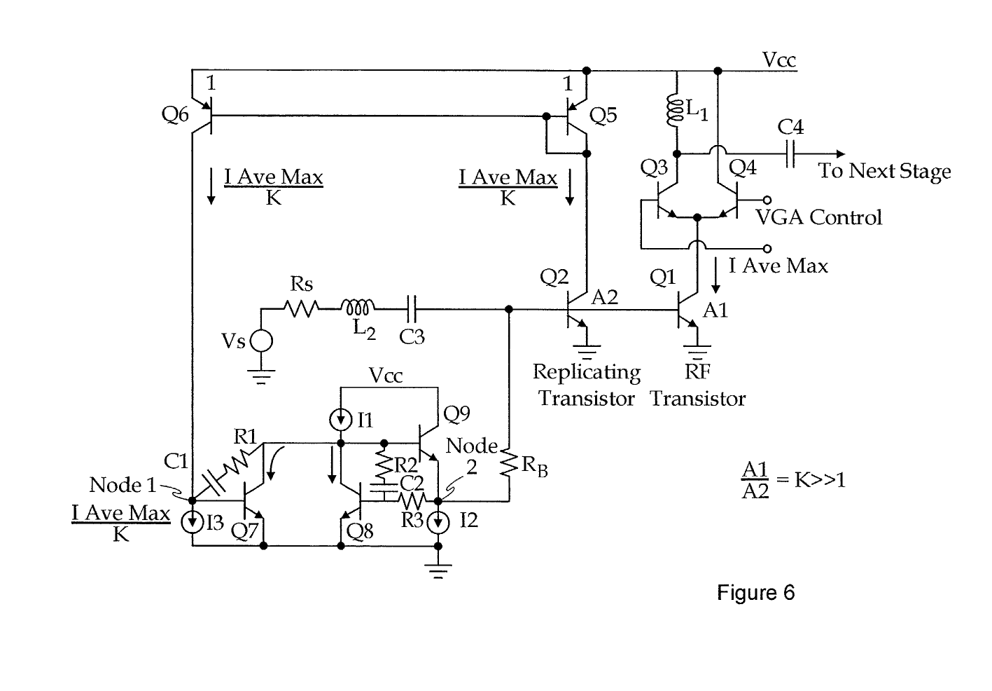

Now referring to FIG. 6, an alternate embodiment of the present invention may be seen. As before, the collector current in transistor Q1, or any desired part thereof, may be steered through transistor Q3 and coupled through capacitor C4 to the next amplifier stage, with any remaining collector current of transistor Q1 passing through transistor Q4, dependent upon the VGA control signal applied to the bases of transistors Q3 and Q4. Also, as before, inductor L1 provides DC coupling to the collector of transistor Q3, though isolates the RF signal in the collector of transistor Q3 from the power supply terminal VCC for coupling to the next stage. Also as before, the VGA control signal may be a differential control signal, or one of the VGA control terminals may be coupled to a reference voltage for signal-ended VGA control via the other VGA control terminal.

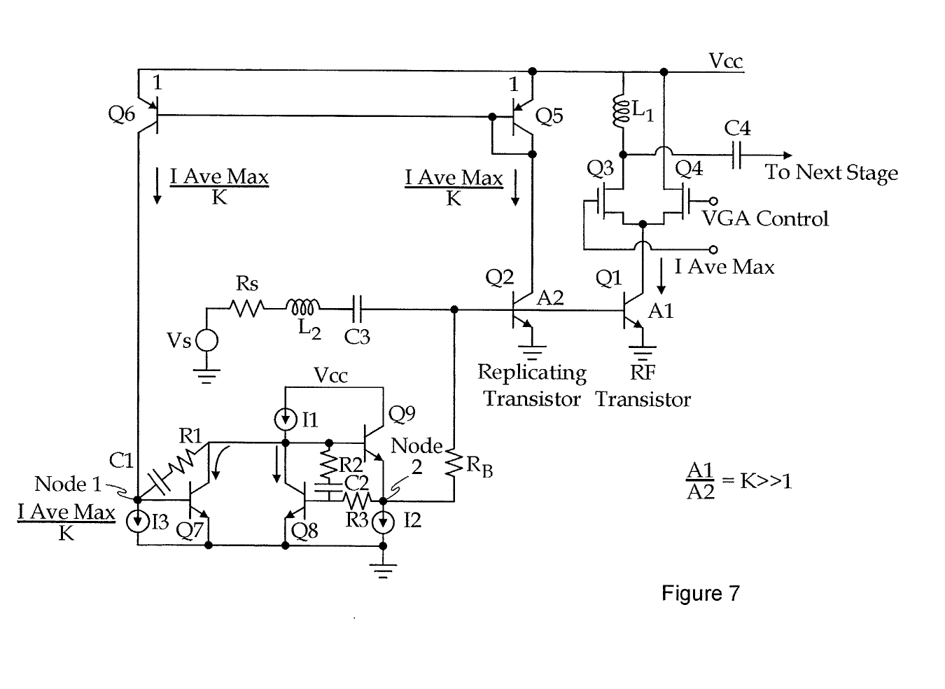

In another embodiment, as illustrated in FIG. 7, transistors Q3 and Q4 may be field effect transistors without deviating from the invention.

The input signal in this embodiment is coupled through a source resistor RS, inductor L2 and DC blocking capacitor C3 to the bases of transistors Q2 and Q1. The inductor L2 is for impedance matching. Transistor Q2 is a replica transistor for transistor Q1, preferably having an area much less than transistor Q1. Thus preferably A_{Q1}/A_{Q2}=K, where K>>1. Thus the collector current in transistor Q2 replicates the collector current in transistor Q1 in the ratio of 1/K. This current is mirrored by transistors Q5 and Q6 to a current summing point at node 1.

Current source I₁ establishes the collector current in transistor Q8 to establish the proper bias voltage through the bias feed resistor R_{B}.

Assume for purposes of explanation that transistors Q7, Q8 and Q9 are substantially identical transistors and that base currents can be neglected. Transistors Q8 and Q1 act as a current mirror, mirroring the current in transistor Q8 to transistors Q1 and Q2. Transistor Q2 in turn mirrors its current through transistors Q5 and Q6 to the summing point at node 1. The various parameters of the circuit are preferably chosen so that when the input signal VS is low or zero, the current mirrored through transistor Q6 to node 1 is less than that of the current source I3. Consequently transistor Q7 will be off, and all of the current of current source I1 will pass through transistor Q8, and be mirrored to transistors Q1 and Q2 as stated before. This establishes the nominal bias current in transistor Q1.

As the input signal VS increases, the negative going output signal component will begin to clip, as described with respect to the previous embodiment. This will cause an increase in the average collector current in transistors Q1 and Q2, and thus an increase in the average current mirrored through transistor Q6 to node 1 (resistor R1 and capacitor C1 providing circuit compensation, and signal frequency filtering for node 1). As the input signal VS further increases, the current mirrored through transistor Q6 will equal the current of current source T3. Further increases in the input signal VS will cause the current mirrored through transistor Q6 to turn on transistor Q7, diverting part of the current from current source I1 to transistor Q7. This in turn reduces the current in transistor Q8, reducing the bias current mirrored to transistors Q1 and Q2, thereby reducing their bias current until the average current through transistor Q6 equals the current of current source I3 (neglecting the base current of transistor Q7).

Thus for a zero input signal, the bias collector current in transistor Q1 will be CI₁, where C is a constant less than, equal to or larger than 1. Now assume transistors Q8 and Q1 are 1/K times the size of transistor Q1. As the input signal increases, the average collector current I_{AVE} in transistor Q1 will increase until the current through transistor Q6, I_{AVG}/K, is equal to I3, after which I_{AVE} will be limited to approximately I_{AVEMAX}/K. Thus in this embodiment, the average collector current in transistor Q1 is allowed to vary for low and moderate input signals, but is limited for large input signals to avoid overwhelming the circuits following the transconductance amplifier Q1. This may also be important to maintain stability in the amplifier.

In any of the foregoing embodiments, or other embodiments as will be obvious to those skilled in the art from the disclosure herein, the transistors, such as in the Stage 1 amplifier and/or the VGA in the embodiments disclosed, may be any type of transistors, including but not necessarily limited to those earlier enumerated. While in the embodiments disclosed, the transistors in the VGA will typically be of the same type, the transistor of Stage 1 may be of the same type or of a different type than those in the VGA. The transistors may also be of either conductivity type by making modifications to the circuits as appropriate.

While the invention has been described and illustrated in detail with respect to exemplary embodiments for wireless devices such as cell phones, other portable and hand held devices and the like, it is to be understood that this is intended by way of illustration and example only and is not to be taken by way of limitation, the spirit and scope of this invention being limited by the terms of the following claims.

What is claimed is:

1. A power amplifier comprising:
a first transconductance amplifier to receive an input signal and provide an output signal, the first transconductance amplifier operating as a class A amplifier for input signals in a first range and as a class AB amplifier for input signals in a second range larger than the first range; and,
a circuit to limit the average current of the output signal to a predetermined maximum average current, independent of the class of operation of the first transconductance amplifier.

2. The power amplifier of claim 1 wherein the predetermined maximum average current is equal to the average current of the output signal for class A operation of the first transconductance amplifier.

3. The power amplifier of claim 1 wherein the predetermined maximum average current is greater than the average current of the output signal for class A operation of the first transconductance amplifier.

4. The power amplifier of claim 1 wherein the first transconductance amplifier also operates as a class B and as a class C amplifier, depending on the size of the input signal.

5. The power amplifier of claim 1 wherein the input signal is an RF signal.

6. The power amplifier of claim 1 wherein the first amplifier includes a first transistor, the emitter of the first transistor being coupled to a power supply terminal through a first resistor, the base of the first transistor to receive the input signal, and the collector of the first transistor to provide the output signal.

7. The device of claim 1 wherein the circuit to maintain the average current of the output signal includes a second transconductance amplifier including:
a first input coupled through a second resistor to the emitter of the first transistor, and through a capacitor to the first power supply terminal;
a second input coupled to a reference voltage; and,
a first output coupled to the base of the first transistor to hold the average current of the output signal of the first transistor substantially constant despite the changing amplitude of the input signal.

8. The power amplifier of claim 1 further comprising:
a second amplifier coupled to the first amplifier to receive the output signal of the first amplifier and configured to receive power control signals to vary the power of the output signal of the second amplifier.

9. The power amplifier of claim 8 wherein the second amplifier includes a first transistor and a second transistor configured as differential current steering transistors,
the emitters of the first and second transistors configured to receive the output signal from the first amplifier,
the bases of the first and second transistors of the second amplifier configured receive the power control signals to vary the power of the output signal, and
the collector of the second transistor to provide the output signal of the second amplifier.

10. The power amplifier of claim 8 wherein the second amplifier includes a first field effect transistor and a second field effect transistor configured as differential current steering transistors,
the source of the first and second field effect transistors configured to receive the output signal from the first amplifier,
the gate of the first and second field effect transistors of the second amplifier configured receive the power control signals to vary the power of the output signal, and
the drain of the second field effect transistor to provide the output signal of the second amplifier.

11. A power amplifier comprising:
transconductance amplifying means for amplifying a radio frequency (RF) signal, the transconductance amplifying means operating as one of a class A and a class AB amplifier depending on the magnitude of the RF signal; and,
means for limiting the average output current of the transconductance amplifying means to a predetermined maximum average output current, despite a changing magnitude of the RF signal.

12. The power amplifier of claim 11 wherein the predetermined maximum average output current is equal to the average output current for class A operation of the transconductance amplifying means.

13. The power amplifier of claim 11 wherein the predetermined maximum average output current is greater than the average output current for class A operation of the transconductance amplifying means.

14. The power amplifier of claim 11 wherein the first amplifier also operates as a class C amplifier depending on the magnitude of the RF signal.

15. The power amplifier of claim 11 further comprised of a current steering means coupled to the output of the transconductance amplifying means for controllably steering any part of the output of the transconductance amplifying means to the output of the current steering means.

16. A method of controlling the output of a transconductance amplifier operating in any of multiple classes of operation comprising maintaining the average output current of the transconductance amplifier to no more than a maximum average output current independent of the class of operation of the transconductance amplifier.

17. The method of claim 16 wherein the average output current of the transconductance amplifier for class A operation is less than the maximum average output current.

18. The method of claim 16 wherein the average output current of the transconductance amplifier for class A operation is equal to the maximum average output current.

19. A method of controlling the output of an RF amplifier having an input transconductance amplifier operating in any of multiple classes of operation maintaining the average output current of the transconductance amplifier to no more than a maximum average output current independent of the class of operation of the transconductance amplifier, and steering all or any part of the output current of the transconductance amplifier to the output of the RF amplifier.

20. The method of claim 19 wherein the average output current of the input transconductance amplifier for class A operation is less than the maximum average output current.

21. The method of claim 19 wherein the average output current of the input transconductance amplifier for class A operation is equal to the maximum average output current.
